(19) United States
(12) Patent Application Publication
(10) Pub. No.: US 2026/0308759 A1
(43) Pub. Date: Oct. 8, 2026

(54) DEVICE AND METHOD FOR MIST CHEMICAL VAPOR DEPOSITION OF LARGE-SIZE SEMICONDUCTOR THIN FILM

(71) Applicant: TIANGONG UNIVERSITY, Tianjin (CN)

(72) Inventors: Pingfan NING, Tianjin (CN); Xiongjie LI, Tianjin (CN); Pingjuan NIU, Tianjin (CN); Yong JIANG, Tianjin (CN)

(21) Appl. No.: 19/370,552

(22) Filed: Oct. 27, 2025

(30) Foreign Application Priority Data
Apr. 8, 2025 (CN) 202510428479.7

(51) Int. Cl. C23C 16/448; C23C 16/40; C23C 16/44; C23C 16/455; C23C 16/458; C23C 16/56; C30B 25/08; C30B 25/12; C30B 25/14; C30B 29/16; C30B 33/04; H01L 21/02

(52) U.S. Cl. CPC C23C 16/4486; C23C 16/40; C23C 16/4409; C23C 16/4412; C23C 16/45565; C23C 16/4584; C23C 16/56; C30B 25/08; C30B 25/12; C30B 25/14; C30B 29/16; C30B 33/04; H10P 14/24; H10P 14/3434

(57) ABSTRACT

Provided are a device for mist chemical vapor deposition of a large-size semiconductor thin film and a method for the mist chemical vapor deposition of a large-size semiconductor thin film. A buffer showerhead is arranged inside a reactor of the device. By designing a structure of the buffer showerhead, epitaxial growth of large-size gallium oxide thin films with various crystal phases and uniform thickness can be achieved.

### CROSS-REFERENCE TO RELATED APPLICATION

This patent application claims the benefit and priority of Chinese Patent Application No. 202510428479.7 filed with the China National Intellectual Property Administration on Apr. 8, 2025, the disclosure of which is incorporated by reference herein in its entirety as part of the present application.

### TECHNICAL FIELD

The present disclosure belongs to the field of growth of semiconductor thin films, and in particular to a device and method for mist chemical vapor deposition of a large-size semiconductor thin film.

### BACKGROUND

Technological progress and the development of society towards intelligence have promoted the upgrading and development of semiconductor materials. Semiconductor materials have experienced the first generation dominated by silicon and germanium, the second generation represented by gallium arsenide, and the third generation represented by silicon carbide and gallium nitride. The development of these semiconductor materials serves as the cornerstone for constant innovation of electronic products, meeting the demands of social development. However, application scenarios of high-power electronic devices, such as large-size aircraft, aerospace vehicles, large vessels and power transmission, put forward requirements on higher power density and greater voltage resistance. This requires the discovery and research of new semiconductor materials that meet the requirements.

Ultra-wide band gap semiconductor materials, due to their large band gap width, can theoretically meet the application requirements of high-power electronic devices. Although aluminum nitride, diamond and the like have very large band gap widths, it is difficult to prepare a large-size single crystal material, so it is not easy to be applied to high-power electronic devices on a large scale.

In contrast, gallium oxide material has excellent application prospects in the fields of power devices and deep ultraviolet electrical devices due to its large band gap width (4.9-5.5 eV), high breakdown field strength (8 MV/cm), large Baliga figure of merit (3,400) and high stability.

Gallium oxide has five different crystal structures as follows: α, β, γ, δ and ε, where β phase is a thermodynamically stable phase of gallium oxide, and other phases of gallium oxide can be transformed into β phase under certain temperature and humidity conditions, but a monoclinic structure of gallium oxide makes the quality of heteroepitaxial β gallium oxide crystal relatively low. A metastable phase of α-phase gallium oxide is of a hexagonal structure, which is easy for heteroepitaxy to obtain a high-quality epitaxial thin film. Compared with β phase, α-phase gallium oxide has a larger band gap width (5.3 eV), making α-phase gallium oxide more suitable for the high-power density device. Moreover, α-phase gallium oxide has a same lattice structure as aluminum oxide, indium oxide, iridium oxide and the like, allowing its band gap width to be regulated in the form of alloy oxide, which makes α-phase gallium oxide have irreplaceable advantages in the application of deep-ultraviolet photoelectric devices.

At present, α-Ga₂O₃ can only be prepared by heteroepitaxy. The commonly used methods for preparing the α-Ga₂O₃ thin film include: metal oxide chemical vapor deposition (MOCVD), low-pressure chemical vapor deposition (LPCVD), molecular beam epitaxy (MBE), halide vapor phase epitaxy (HVPE), atomic layer deposition (ALD), pulsed laser deposition (PLD) and mist-chemical vapor deposition (Mist-CVD). The mist-chemical vapor deposition (Mist-CVD) method does not need high vacuum conditions, and has a simple equipment structure, rapid thin film growth rate and low epitaxial cost. Therefore, the research on the equipment and processes for preparing gallium oxide thin films using the mist-chemical vapor deposition (Mist-CVD) method is becoming more and more perfect.

There is no relevant industry standard for mist-chemical vapor deposition (Mist-CVD) equipment, so the structure of mist-chemical vapor deposition (Mist-CVD) equipment used by various scientific research units is flexible and diverse. At present, the common mist-chemical vapor deposition (Mist-CVD) equipment mainly includes two types: horizontal type (slit structure) and vertical type (hot-wall heating tube furnace). When a large-size (two inches or more) gallium oxide thin film is prepared in the horizontal equipment, a thickness of the thin film gradually decreases along a carrier gas conveying direction, resulting in extremely nonuniform thin film thickness. Similarly, when the large-size (two inches or more) gallium oxide thin film is prepared in the vertical equipment, the thin film is difficult to completely cover the whole substrate, and the thickness distribution of the thin film along a radial direction of the substrate is nonuniform, which greatly restricts the development of gallium oxide power devices.

### SUMMARY

In view of this, the present disclosure aims at providing a device and method for mist chemical vapor deposition of a large-size semiconductor thin film to overcome the problem of nonuniform growth thickness of a gallium oxide thin film grew by using an existing mist-chemical vapor deposition technology.

To achieve the foregoing objective, the present disclosure employs the technical solutions as follows.

A device for mist chemical vapor deposition of a large-size semiconductor thin film includes an atomization unit, a reactor, a buffer showerhead, and a rotary base.

The buffer showerhead is arranged inside the reactor, and the buffer showerhead includes a conveying pipe, a conical transition segment and a cylindrical segment connected in sequence from left to right; the conveying pipe passes through one end of the reactor and is connected to the atomization unit, and the atomization unit is further provided with a carrier gas input port. A first buffer plate and a second buffer plate are arranged in the cylindrical segment in sequence from left to right, and the first buffer plate and the second buffer plate divide the cylindrical segment into three portions, and the three portions are a first buffer area, a second buffer area and a growing area. The first buffer plate is of a conical plate structure, the second buffer plate is a circular flat panel, the first buffer plate is provided with multiple straight holes perpendicular to the second buffer plate, and the second buffer plate is provided with multiple inclined holes. The rotary base directly opposite to the second buffer plate is arranged at the growing area, and a substrate is fixed onto the rotary base and is surrounded by a cylindrical segment of the growing area. The rotary base is driven to rotate by a first motor arranged outside the reactor, the first motor is mounted on a mobile unit, and the mobile unit drives the first motor and the rotary base to move toward a direction close to or away from the second buffer plate.

In some embodiments, a diameter of each of the straight holes is 2 mm-10 mm, and a distance between every two adjacent straight holes is 2 mm-5 mm; and a diameter of the inclined hole is 2 mm-10 mm.

The diameter of the straight hole is equal to the diameter of the inclined hole.

In an embodiment, the inclined holes and the straight holes are equal in number and in a one-to-one correspondence; and an included angle between a central axis of the inclined hole and a surface normal of the second buffer plate is 30°-70°.

In some embodiments, the cylindrical segment has a length of 50 mm-300 mm, a distance between a center of the first buffer plate and a center of the second buffer plate is 10 mm-200 mm, an included angle α of an apex angle of the first buffer plate is 90°-175°, and a distance between the second buffer plate and the substrate is 0.5 mm-50 mm.

In some embodiments, the mobile unit includes a motion bracket and a drive mechanism. The drive mechanism includes a screw, a sliding rod, a second motor, and a bracket. The screw and the sliding rod are arranged on the bracket in parallel, the second motor is in transmission connection with the screw, the motion bracket is slidingly arranged on the sliding rod, the motion bracket is threaded to the screw, and the first motor is mounted on the motion bracket.

In addition, the mobile unit is not limited to the foregoing structure, and any mechanism that can drive the motion bracket to move back and forth can be applied to the present disclosure.

In some embodiments, a cylinder with two open ends and sealing flange plates fixed to the two ends of the cylinder, the conveying pipe passes through one sealing flange plate, and a rotating shaft for connecting the rotary base and the first motor passes through an other sealing flange plate. An exhaust pipe is also connected to the other sealing flange plate, and the exhaust pipe is connected to an exhaust treatment unit. A heating layer is also arranged on a sidewall of the cylinder.

The sealing flange plate can be fixed via bolts, or a hoops.

An exhaust treatment unit includes an alkaline gas washing bottle, an acidic gas washing bottle, and an adsorption bottle which are connected in sequence. The alkaline gas washing bottle contains an alkaline solution for removing acidic substances contained in a waste gas. The acidic gas washing bottle contains an acid solution for removing alkaline substances contained in the waste gas. The adsorption bottle contains activated carbon and desiccant for adsorbing other harmful substances in the waste gas.

In some embodiments, a side surface, directly opposite to the second buffer plate, of the rotary base is provided with a groove, a center of the groove is provided with a boss for placing the substrate, two to six bolts are screwed to a sidewall of the groove, and one end, extending into the groove, of each of the bolts is rotatably connected to a top plate. The substrate is placed inside the groove, and by adjusting the bolts, the top plate can clamp the substrate for fixation.

In addition, a structure for fixing the substrate is not limited to the foregoing structure, the substrate can be fixed by arranging a pressing plate on the rotary base, where the pressing plate is configured to press against a surface of the substrate to fix the substrate; or the substrate can be fixed by using a negative pressure adsorption manner, where an air hole is formed in the rotary base, and the rotary base is connected to a negative pressure system.

In some embodiments, the reactor is internally provided with a neutron irradiation unit is arranged inside the reactor directly opposite the growing area.

The neutron irradiation unit is a neutron source, and specific equipment can employ a laser neutron source.

In some embodiments, electrode plates for generating an accelerated electric field are also arranged at two ends of the reactor, a field strength range of the generated accelerated electric field is 500 V-10 kV/m, and a direction of the accelerated electric field is consistent with a carrier gas direction.

An electrode for generating a high-voltage electrostatic field is also arranged at a gas outlet of the atomization unit.

In an embodiment, an electric field electrode plate is arranged at an inner side of the sealing flange plate at each of two ends of the reactor to provide an accelerated electric field required for controlling the motion of droplets.

The present disclosure further provides a method for mist chemical vapor deposition of a large-size semiconductor thin film. The method uses the device for mist chemical vapor deposition of a large-size semiconductor thin film described above, and the method includes the following steps:
S1, fixing a cleaned substrate onto the rotary base, and moving, by the mobile unit, the substrate to the growing area to directly face the second buffer plate;
S2, adding a configured reaction source solution into the atomization unit;
S3, evacuating residual gas in the reactor with nitrogen, and preheating the reactor;
S4, starting the atomization unit after preheating, and atomizing the reaction source solution to form uniform droplets;
S5, introducing the carrier gas, where the carrier gas entrains the droplets to enter the reactor, and growing a gallium oxide thin film on the substrate; and
S6, upon completion of gallium oxide thin film growth, turning off an atomization device and the carrier gas, and maintaining a temperature of the reactor; starting continuous introduction of the carrier gas to evacuate residual reactants and byproducts from a reaction chamber, gradually cooling the reaction chamber to a room temperature, and taking out a sample.

As an example, the method further includes the following steps: in S5, growing the thin film for 5 min-60 min, turning off the atomization device, turning on a neutron irradiation unit to perform neutron irradiation on the grown thin film, where an irradiation dose is set to 500 kGy-5000 kGy with a duration of 30 s-300 s; upon completion of irradiation, maintaining heating for 3 min-15 min; and repeating the step for 2-10 times; or

The method further includes the following steps: after a forming of uniform droplets in S4, activating a high-voltage electrostatic field to charge the droplets, where a field strength range of the high-voltage electrostatic field is 5 kV-100 kV/m; meanwhile activating an accelerated electric field, where a field strength range of the accelerated electric field is 500 V-10 kV/m.

The electrostatic field is an electric field for charging the droplets, a method for charging the droplets is induction charging, and the high-voltage electrostatic field is an optional accessory for the atomization unit, which is arranged inside the reactor. The droplets are positively charged, and a direction of the accelerated electric field is consistent with a direction of the carrier gas.

Compared with the prior art, the device and method for mist chemical vapor deposition of large-size semiconductor thin film provided by the present disclosure have the following advantages:

The device for mist chemical vapor deposition of a large-size semiconductor thin film provided by the present disclosure can achieve epitaxial growth of large-size gallium oxide thin films with various crystal phases and uniform thickness. In addition, neutron irradiation may also reduce the defect density of thin films.

### BRIEF DESCRIPTION OF THE DRAWINGS

The drawings, which constitute a part of the present disclosure, serve to provide a further understanding of the present disclosure. Illustrative embodiments of the present disclosure and descriptions thereof are used to explain the present disclosure and do not constitute improper limitations on the present disclosure. In the drawings:

FIG. 1 is a schematic structural diagram of a device for mist chemical vapor deposition of a large-size semiconductor thin film according to an embodiment of the present disclosure;

FIG. 2 is a schematic structural diagram of a horizontal device for mist chemical vapor deposition of a large-size semiconductor thin film according to an embodiment of the present disclosure;

FIG. 3 is a schematic structural diagram of a vertical device for mist chemical vapor deposition of a large-size semiconductor thin film according to an embodiment of the present disclosure;

FIG. 4 shows a first structure of a deposition showerhead according to an embodiment of the present disclosure;

FIG. 5 shows a second structure of a deposition showerhead according to an embodiment of the present disclosure;

FIG. 6 is a structural diagram of a rotary base according to an embodiment of the present disclosure;

FIG. 7 shows a thin film prepared according to Embodiment I of the present disclosure;

FIG. 8 shows a thin film prepared according to Embodiment II of the present disclosure;

FIG. 9 shows cross-sectional flow velocity distribution of a gas ejected from a spray showerhead without a buffer structure according to an embodiment of the present disclosure;

FIG. 10 shows cross-sectional flow velocity distribution of a gas ejected from a spray showerhead with a buffer structure according to Embodiment I of the present disclosure.

### REFERENCE NUMERALS ARE DESCRIBED AS FOLLOWS

1—atomization unit; 2—reactor; 21—cylinder; 22—sealing flange plate; 221—exhaust pipe; 222—exhaust treatment unit; 23—heating layer; 3—buffer showerhead; 31—conveying pipe; 32—conical transition segment; 33—cylindrical segment; 34—first buffer plate; 35—second buffer plate; 4—rotary base; 41—groove; 42—boss; 43—bolt; 44—top plate; 5—rotating shaft; 6—first motor; 7—motion bracket; 8—drive mechanism; 81—screw; 82—sliding rod; 83—second motor; 84—bracket; 9—neutron irradiation unit.

### DETAILED DESCRIPTION OF THE EMBODIMENTS

It should be noted that embodiments in the present disclosure and features in the embodiments can be mutually combined in the case of no conflict.

In the description of the present disclosure, it should be understood that the orientation or positional relationship indicated by terms such as “center”, “longitudinal”, “transverse”, “upper”, “lower”, “front”, “back”, “left”, “right”, “vertical”, “horizontal”, “top”, “bottom”, “inside” and “outside” is based on the orientation or positional relationship shown in the drawings, and is only for convenience of description of the present disclosure and simplification of description, rather than indicating or implying that the referred device or element must have a particular orientation and be constructed and operated in a particular orientation, and thus is not to be construed as limiting the present disclosure. In addition, the terms such as “first” and “second” in the present disclosure are only used for descriptive purposes, and cannot be construed as indicating or implying their relative importance or implicitly indicating the number of indicated technical features. Therefore, the features defined with “first” and “second”, etc may explicitly or implicitly include one or more of the features. In the description of the present disclosure, unless otherwise specified, “a plurality of” means two or more.

In the description of the present disclosure, unless expressly specified and limited otherwise, it should be noted that the terms “mount”, “connect”, “connection” and the like should be understood broadly, e.g., it may be a fixed connection, a detachable connection, or an integrated connection; it may be a mechanical connection, or an electrical connection; it may be a direct connection, an indirect connection through an intermediate medium, or an internal communication between the two elements. For those of ordinary skill in the art, the specific meanings of the above terms in the present disclosure can be understood on a case-by-case basis.

The following clearly and completely describes the technical solutions in the embodiments of the present disclosure with reference to the accompanying drawings in the embodiments of the present disclosure. Apparently, the described embodiments are merely a part rather than all of the embodiments of the present disclosure. Based on the embodiments of the present disclosure, all other embodiments obtained by those of ordinary skill in the art without creative efforts shall fall within the scope of protection of the present disclosure.

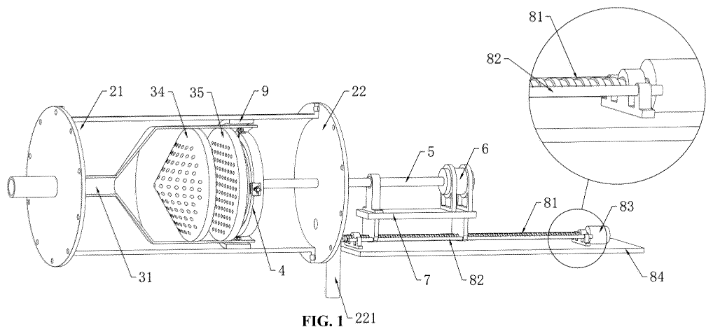

As shown in FIG. 1, a device for mist chemical vapor deposition of a large-size semiconductor thin film includes an atomization unit 1, a reactor 2, a buffer showerhead 3, and a rotary base 4.

The atomization unit 1 is configured to atomize a reaction source solution to form droplets. The atomization means are not limited, which may be high-pressure airless atomization, gas atomization, ultrasonic atomization, electrostatic atomization and the like.

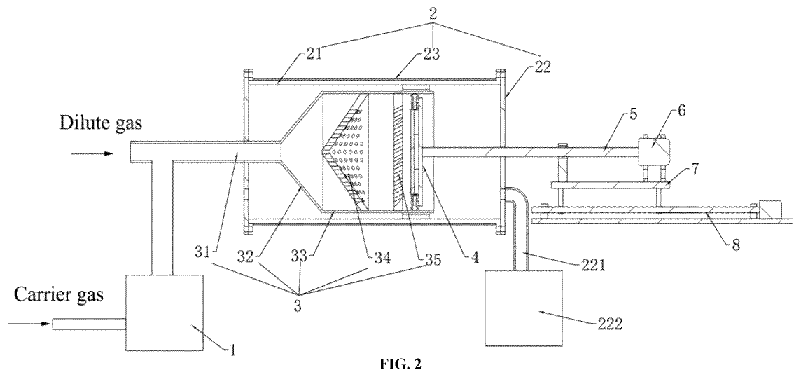

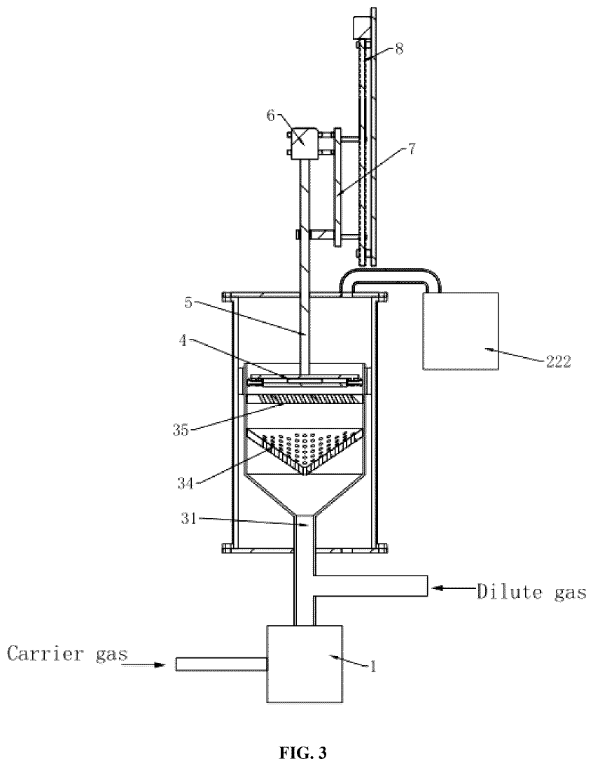

The reactor 2 provides required environment conditions such as a temperature and a degree of vacuum for epitaxial growth of a thin film, a spatial position of the reactor 2 is not limited, which may be horizontal, vertical, or inclined in any angle. As shown, FIG. 2 is a schematic structural diagram of a horizontal device for mist chemical vapor deposition of a large-size semiconductor thin film; and FIG. 3 is a schematic structural diagram of a vertical device for mist chemical vapor deposition of a large-size semiconductor thin film. A temperature environment provided by the reactor 2 can range from −196° C. to 1800° C., and the degree of vacuum can range from 1×10⁻⁴ Pa to multiples of atmospheric pressure.

The buffer showerhead 3 is made of a high-temperature-resistant material, which includes, but is not limited to quartz, graphite, stainless steel, superalloys, and the like.

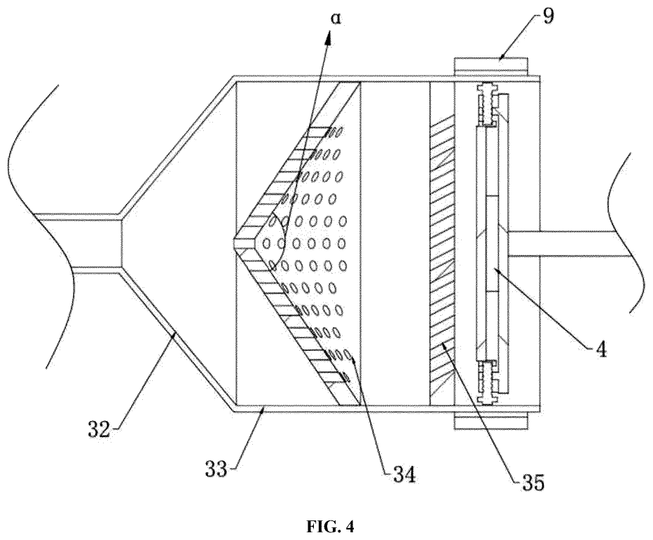

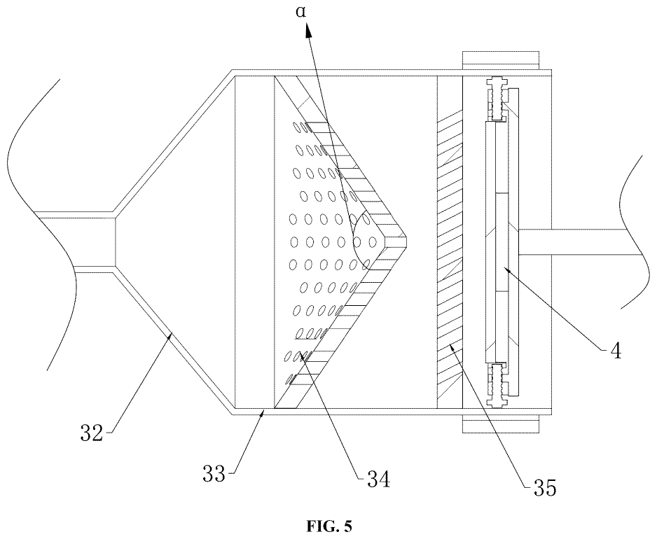

A structure of the buffer showerhead 3 is as shown in FIG. 4 and FIG. 5. The buffer showerhead 3 is arranged inside the reactor 2, and includes a conveying pipe 31, a conical transition segment 32, and a cylindrical segment 33 connected in turn from left to right, where the cylindrical segment has a diameter of 60 mm-600 mm. The conveying pipe 31 passes through one end of the reactor 2 and is connected to the atomization unit 1, and the atomization unit 1 is further provided with a carrier gas input port. A first buffer plate 34 and a second buffer plate 35 are arranged in the cylindrical segment 33 in turn from left to right to divide the cylindrical segment 33 into three portions, and the three portions are a first buffer area, a second buffer area and a growing area in turn from left to right. The first buffer plate 34 is of a conical plate structure, and an apex of the conical plate structure may face towards or is away from the second buffer plate 35. The second buffer plate 35 is a circular flat panel, the first buffer plate 34 is provided with multiple straight holes perpendicular to the second buffer plate 35, and the second buffer plate 35 is provided with multiple inclined holes. An array arrangement form of the straight holes and inclined holes is not limited, which may be a tight hexagonal array, a rectangular array and so on. The growing area is provided with a rotary base 4 directly opposite to the second buffer plate 35, a substrate is fixed onto the rotary base 4 and is surrounded by the cylindrical segment 33 of the growing area. The rotary base 4 is driven to rotate by a first motor 6 arranged outside the reactor 2, the first motor 6 is mounted on a mobile unit, and the mobile unit drives the first motor 6 and the rotary base 4 to move toward a direction close to or away from the second buffer plate 35.

The substrate rotates with the rotary base 4, and under the action of a carrier gas, the droplets reach the growing area after passing through the first buffer plate 34 and the second buffer plate and carry out thin film growth on the substrate. When the droplets pass through the first buffer plate 34, a velocity distribution of the mist in the buffer area quickly tends to be uniform, and when the droplets pass through the second buffer plate 35, a direction of the mist flow is changed. The combination of the two buffer plates can make the mist flow uniformly sprayed to the surface of the substrate at a certain angle.

Opening size and shape of the conveying pipe 31 are not particularly limited, where the shape may be circular, oval, rectangular, irregular and the like, and an inner diameter of the size opening may be 10 mm-300 mm.

As shown in FIG. 2 and FIG. 3, diluent gas can also be introduced into the conveying pipe 31, and the diluent gas can adjust a concentration of the mist to affect a growth rate of the thin film, thereby achieving the purpose of controlling the film thickness.

In some embodiments, a diameter of the straight hole is 2 mm-10 mm, and a distance between every two adjacent straight holes is 2 mm-5 mm; and diameter of the inclined hole is 2 mm-10 mm.

The diameter of the straight hole is equal to that of the inclined hole.

In some embodiments, the inclined holes and the straight holes are equal in number and in a one-to-one correspondence; and the manner of one-to-one correspondence has little influence on the velocity of the mist flow.

An included angle between a central axis of the inclined hole and a surface normal of the second buffer plate is 30°-70°.

The inclined holes are arranged to facilitate the mist of reaction raw materials to reach the surface of the substrate at a certain angle, so that the distribution of the mist on the surface of the substrate is more uniform, and the thickness of the thin film is more uniform.

In some embodiments, the cylindrical segment 3 has a length of 50 mm-300 mm, a distance between the center of the first buffer plate 34 and the center of the second buffer plate 35 is 10 mm-200 mm, an included angle α of an apex angle of the first buffer plate 34 is 90°-175°, and a distance between the second buffer plate 35 and the substrate is 0.5 mm-50 mm.

In some embodiments, the mobile unit includes a motion bracket 7 and a drive mechanism 8. The drive mechanism 8 includes a screw 81, a sliding rod 82, a second motor 83, and a bracket 84. The screw 81 and the sliding rod 82 are arranged on the bracket in parallel, the second motor 83 is in transmission connection with the screw 81, the motion bracket 7 is slidingly arranged on the sliding rod 82, the motion bracket 7 is threaded to the screw 81, and the first motor 6 is mounted on the motion bracket 7.

In addition, the mobile unit is not limited to the foregoing structure, and any mechanism that can drive the motion bracket 7 to move back and forth can be applied to the present disclosure.

In some embodiments, the reactor 2 includes a cylinder 21 with openings at two ends of the cylinder 21 and sealing flange plates 22 fixed to two ends of the cylinder 21. The conveying pipe 31 passes through one sealing flange plate 22, and a rotating shaft 5 for connecting the rotary base 4 and the first motor 6 passes through the other sealing flange plate 22, an exhaust pipe 221 is also connected to the other sealing flange plate 22, and the exhaust pipe 221 is connected to an exhaust treatment unit 22. A heating layer 23 is also arranged on a sidewall of the cylinder 21.

The sealing flange plate 22 can be fixed via bolts, or can also be fixed via hoops.

An exhaust treatment unit 222 includes an alkaline gas washing bottle, an acidic gas washing bottle, and an adsorption bottle. The alkaline gas washing bottle contains an alkaline solution for removing acidic substances contained in a waste gas; the acidic gas washing bottle contains an acid solution for removing alkaline substances contained in the waste gas; and the adsorption bottle contains activated carbon and desiccant for adsorbing other harmful substances in the waste gas.

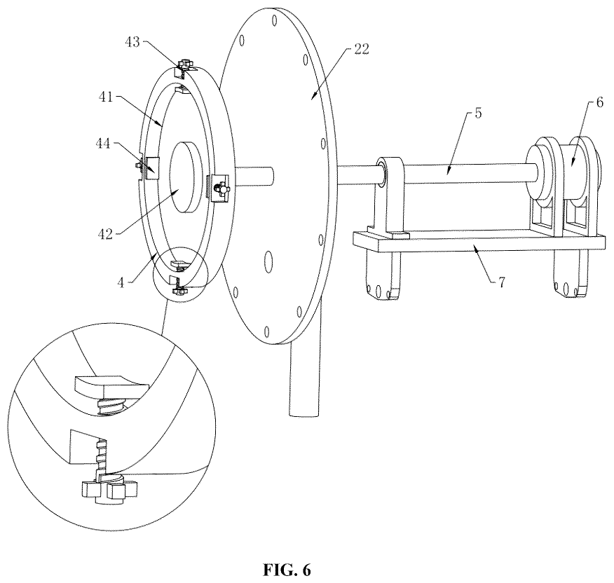

In some embodiments, as shown in FIG. 6, a side surface, directly opposite to the second buffer plate 35, of the rotary base 4 is provided with a groove 41, the center of the groove 41 is provided with a boss 42 for placing the substrate; two to six bolts 43 are screwed to a sidewall of the groove 41, and one end, extending into the groove 41, of each bolt 43 is rotatably connected to a top plate 44. The substrate is placed inside the groove 41, and by adjusting the bolt 43, the substrate can be clamped by the top plate 44 for fixation.

In addition, a structure for fixing the substrate is not limited to the foregoing structure, the substrate may be fixed by arranging a pressing plate on the rotary base 4, where the pressing plate is configured to press against a surface of the substrate to fix the substrate. The substrate can be fixed by using a negative pressure adsorption manner, an air hole is formed in the rotary base 4, and the rotary base 4 is connected to a negative pressure system.

In some embodiments, a neutron irradiation unit 9 is also arranged inside the reactor 2 directly opposite to the growing area.

The neutron irradiation unit 9 is a neutron source, and specific equipment can use a laser neutron source.

In some embodiments, electrode plates for generating an accelerated electric field are also arranged at two ends of the reactor, a field strength range of the generated accelerated electric field is 500 V-10 kV/m, and a direction of the accelerated electric field is consistent with a carrier gas direction.

The electrostatic field is an electric field for charging the droplets, a method for charging the droplets is induction charging, and the high-voltage electrostatic field is generated by an electrode arranged at a gas outlet of the atomization unit, and a field strength of the high-voltage electrostatic field is 5 kV-100 kV/m.

More specifically, an electric field electrode plate is arranged at an inner side of the sealing flange plate 22 at two ends of the reactor to provide an accelerated electric field required for controlling the motion of droplets.

The reaction source solution adopted in the present disclosure is a gallium-containing solution. A solvent is not limited, which may be water, ethanol and the like, and may be acidic or neutral. A solute is gallium-containing compound, which may be gallium chloride, gallium acetylacetonate, gallium bromide, gallium sulfate, gallium hydroxide and the like, without specific limitation. A concentration of the reaction source solution (calculated by gallium) can be specifically limited to 0.005 mol/L-0.5 mol/L.

The carrier gas is not specifically limited, which may employ a gas mixture of inert gas and O where nitrogen, which is relatively easy to obtain, is generally used as the inert gas. Adjusting oxygen content in the gas mixture can change a proportion of chemical reaction products and also adjust a reaction rate. The addition of oxygen can improve the crystal quality of the thin film to a certain extent. The reaction rate adjustment here is reflected in the fact that, when an inert gas flow rate remains unchanged, an overall flow rate of the carrier gas increases after the addition of oxygen, the concentration of the mist decreases, and the growth rate of thin films decreases.

Waste gas contains some unreacted reactants and products after reaction. Different reactants make the waste gas contain alkaline or acidic substances, most pollutants can be removed by acidic and alkaline gas washing cylinders, and then the waste gas can be purified by adsorption bottles. An exhaust end of a waste gas treatment device is connected to a negative pressure fan to prevent the exhaust from being sucked back into the reaction chamber.

Embodiment I: Epitaxial growth of two-inch α-Ga₂O₃ thin film on sapphire substrate.

This thin film is prepared by using the vertical device for mist chemical vapor deposition of a large-size semiconductor thin film shown in FIG. 3. On the basis of the foregoing structures, in this embodiment, a structure of a buffer showerhead 3 is as shown in FIG. 4, a cylindrical segment has a diameter of 200 mm and a length of 300 mm; a straight hole has a diameter of 8 mm, a distance between every two adjacent straight holes is 4 mm, and an inclined hole has a diameter of 8 mm. The straight holes are in one-to-one correspondence with the inclined holes, and an included angle between a central axis of the slant hole and a surface normal of a second buffer plate is 45°, so that raw material mist is directed toward a surface of a substrate at 45°. The distance between the center of a first buffer plate and the center of the second buffer plate is 100 mm, and the included angle α of the apex angle of the first buffer plate is 100°.

A preparation method for the thin film is as follows:
1. Substrate cleaning
A sapphire substrate is placed in an ultrasonic cleaning machine containing cleaning liquid and undergoes ultrasonic cleaning for 1 min, and
the substrate is taken out, and then the cleaning liquid remaining on the surface of the substrate is blown dry with nitrogen.
2. A proper quartz rotary base is selected according to the size of the substrate, the sapphire substrate is horizontally fixed to the rotary base, then the rotary base is sent into a reactor by a mobile unit, and the reactor is sealed with a sealing flange plate.
3. The rotary base is adjusted to make the substrate located 2 mm directly above the second buffer plate, where the substrate is parallel to the second buffer plate.
4. A reaction source solution is prepared as follows: 18.5 grams of gallium acetylacetonate powder is dissolved in 2 liters of deionized water to prepare a gallium source solution with a concentration of about 0.025 mol/L, and the prepared reaction source solution is added to an atomization unit.
5. Residual gas in the reactor is evacuated with nitrogen, and preheating is carried out to the reactor. A temperature of the reactor is set to be 650 °C.
6. After preheating, the atomization unit is started, and in the atomization unit, the reaction resource is atomized through an ultrasonic atomization method to form uniform droplets, where an ultrasonic atomization frequency is 3 MHz.
7. A carrier gas is introduced, where nitrogen is employed as the carrier gas, with a flow rate of 400 sccm. The carrier gas entrains the droplets to enter the reactor, and a gallium oxide thin film grows on the substrate. The reactor is kept at a growth temperature and the gallium oxide thin film is begun to grow, where the growth time is set to be 30 min.
8. Upon completion of the growth of the gallium oxide thin film, an atomization device and the carrier gas are turned off, and the temperature of the reactor is kept for 3 min; then the carrier gas is initiated and nitrogen is continuously introduced to evacuate residual reactants and byproducts from a reaction chamber, and the temperature in the reaction chamber is gradually cooled to a room temperature, and then a sample is taken out.

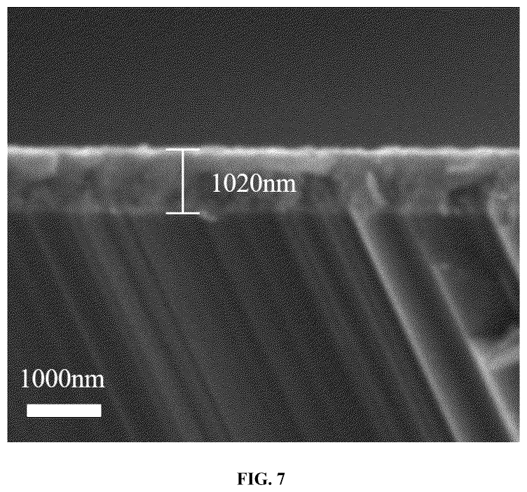

FIG. 7 is a two-inch thin film sample prepared in this embodiment, and a thickness of a tested part in the figure is 1020 nm. 20 points are randomly selected across the prepared thin film for thickness measurement, where an average thickness is 1018 nm, and a thickness standard deviation is only 26 nm, indicating that the gallium oxide thin film with relatively uniform thickness can be prepared by using the device of the present disclosure.

Embodiment II: Epitaxial growth of four-inch α-Ga₂O₃ thin film on sapphire substrate

This thin film is prepared by using the same vertical device for mist chemical vapor deposition of a large-size semiconductor thin film as in Embodiment I.

A preparation method for the thin film is as follows:
1. Substrate cleaning
A sapphire substrate is placed in an ultrasonic cleaning machine containing cleaning liquid and undergoes ultrasonic cleaning for 1 min, and
the substrate is taken out, and then the cleaning liquid remaining on the surface of the substrate is blown dry with nitrogen.
2. A proper quartz rotary base is selected according to the size of the substrate, the sapphire substrate is horizontally fixed onto the rotary base, then the rotary base is sent into a reactor by a mobile unit, and the reactor is sealed with a sealing flange plate.
3. The rotary base is adjusted to make the substrate located 2 mm directly above the second buffer plate, where the substrate is parallel to the second buffer plate.
4. A reaction source solution is prepared as follows: 18.5 grams of gallium acetylacetonate powder is dissolved in 2 liters of deionized water to prepare a gallium source solution with a concentration of about 0.025 mol/L, and the prepared reaction source solution is added to an atomization unit.
5. Residual gas in the reactor is evacuated with nitrogen, and preheating is carried out to the reactor. A temperature of the reactor is set to be 650 °C.
6. After preheating, the atomization unit is started, and in the atomization unit, the reaction resource is atomized through an ultrasonic atomization method to form uniform droplets, where an ultrasonic atomization frequency is 3 MHz.
7. A carrier gas is introduced, where nitrogen is employed as the carrier gas, with a flow rate of 800 sccm. The carrier gas entrains the droplets to enter the reactor, and a gallium oxide thin film grows on the substrate. The reactor is kept at a growth temperature and the gallium oxide thin film is begun to grow, where the growth time is set to be 30 min.
8. Upon completion of the growth of the gallium oxide thin film, an atomization device and the carrier gas are turned off, and the temperature of the reactor is kept for 3 min; then the carrier gas is initiated and nitrogen is continuously introduced to evacuate residual reactants and byproducts from a reaction chamber, and the temperature in the reaction chamber is gradually cooled to a room temperature, and then a sample is taken out.

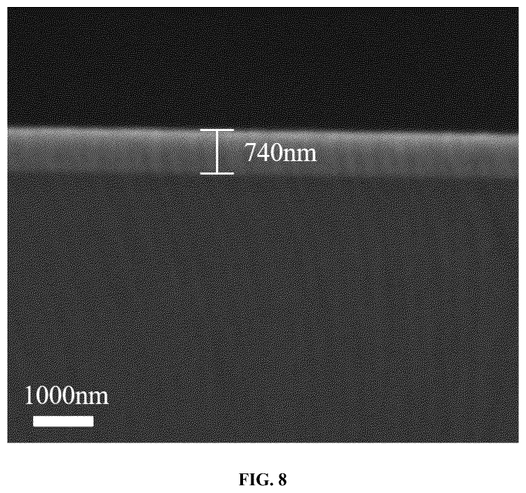

FIG. 8 is a four-inch thin film sample prepared in this embodiment, and a thickness of a texted part in the figure is 740 nm. 20 points are randomly selected across the prepared thin film for thickness measurement, where an average thickness is 742 nm, and a thickness standard deviation is only 43 nm deviated from the standard thickness, indicating that the gallium oxide thin film with relatively uniform thickness can be prepared by using the device of the present disclosure.

Embodiment III: Epitaxial growth of two-inch ε-Ga₂O₃ thin film on sapphire substrate

This thin film is prepared by using the same vertical device for mist chemical vapor deposition of a large-size semiconductor thin film as in Embodiment I. But a tilt angle of the inclined hole is different from that of Embodiment I, an included angle between the central axis of the inclined hole and the surface normal of the second buffer plate is 65°, so that the raw material mist can be directed toward the surface of the substrate at 65°.

A preparation method for the thin film is as follows:
1. Substrate cleaning

A sapphire substrate is placed in an ultrasonic cleaning machine containing cleaning liquid and undergoes ultrasonic cleaning for 1 min, and
the substrate is taken out, and then the cleaning liquid remaining on the surface of the substrate is blown dry with nitrogen.
2. A proper quartz rotary base is selected according to the size of the substrate, the sapphire substrate is horizontally fixed to the rotary base, then the rotary base is sent into a reactor by a mobile unit, and the reactor is sealed with a sealing flange plate.
3. The rotary base is adjusted to make the substrate located 10 mm directly above the second buffer plate, where the substrate is parallel to the second buffer plate.
4. A reaction source solution is prepared as follows: 18.5 grams of gallium acetylacetonate powder is dissolved in 2 liters of deionized water to prepare a gallium source solution with a concentration of about 0.025 mol/L, and the prepared reaction source solution is added to an atomization unit.
5. Residual gas in the reactor is evacuated with nitrogen, and preheating is carried out to the reactor. A temperature of the reactor is set to be 850 °C.
6. After preheating, the atomization unit is started, and in the atomization unit, the reaction resource is atomized through an ultrasonic atomization method to form uniform droplets, where an ultrasonic atomization frequency is 3 MHz.
7. A carrier gas is introduced, where nitrogen is employed as the carrier gas, with a flow rate of 600 sccm. The carrier gas entrains the droplets to enter the reactor, and a gallium oxide thin film grows on the substrate. The reactor is kept at a growth temperature and the gallium oxide thin film is begun to grow, where the growth time is set to be 30 min.
8. Upon completion of the growth of the gallium oxide thin film, an atomization device and the carrier gas are turned off, and the temperature of the reactor is kept for 3 min; then the carrier gas is initiated and nitrogen is continuously introduced to evacuate residual reactants and byproducts from a reaction chamber, and the temperature in the reaction chamber is gradually cooled to a room temperature, and then a sample is taken out.

The gallium oxide thin film with a relatively uniform thickness may also be prepared in this embodiment through measurement.

Embodiment IV: Epitaxial growth of two-inch β-Ga₂O₃ thin film on β-Ga₂O₃ Substrate

This thin film is prepared by using the same vertical device for mist chemical vapor deposition of a large-size semiconductor thin film as in Embodiment I.

A preparation method for the thin film is as follows:
1. Substrate cleaning

A β-Ga₂O₃ substrate is placed in an ultrasonic cleaning machine containing cleaning liquid and undergoes ultrasonic cleaning for 1 min; and
the substrate is taken out, and then the cleaning liquid remaining on the surface of the substrate is blown dry with nitrogen.
2. A proper quartz rotary base is selected according to the size of the substrate, the sapphire substrate is horizontally fixed onto the rotary base, then the rotary base is sent into a reactor by a mobile unit, and the reactor is sealed with a sealing flange plate.
3. The rotary base is adjusted to make the substrate located 2 mm directly above the second buffer plate, where the substrate is parallel to the second buffer plate.
4. A reaction source solution is prepared as follows: 18.5 grams of gallium acetylacetonate powder is dissolved in 2 liters of deionized water to prepare a gallium source solution with a concentration of about 0.025 mol/L, and the prepared reaction source solution is added to an atomization unit.
5. Residual gas in the reactor is evacuated with nitrogen, and preheating is carried out to the reactor. A temperature of the reactor is set to be 950 °C.
6. After preheating, the atomization unit is started, and in the atomization unit, the reaction resource is atomized through an ultrasonic atomization method to form uniform droplets, where an ultrasonic atomization frequency is 3 MHz.
7. A carrier gas is introduced, where nitrogen is employed as the carrier gas, with a flow rate of 2000 sccm. The carrier gas entrains the droplets to enter the reactor, and a gallium oxide thin film grows on the substrate. The reactor is kept at a growth temperature and the gallium oxide thin film is begun to grow, where the growth time is set to be 30 min.
8. Upon completion of the growth of the gallium oxide thin film, an atomization device and the carrier gas are turned off, and the temperature of the reactor is kept for 3 min; then the carrier gas is initiated and nitrogen is continuously introduced to evacuate residual reactants and byproducts from a reaction chamber, and the temperature in the reaction chamber is gradually cooled to a room temperature, and then a sample is taken out.

The gallium oxide thin film with a relatively uniform thickness may also be prepared in this embodiment through measurement.

Embodiment V: Neutron irradiation-induced epitaxial growth of two-inch α-Ga₂O₃ thin film on sapphire substrate

This thin film is prepared by using the same vertical device for mist chemical vapor deposition of a large-size semiconductor thin film as in Embodiment I. In addition, on the basis of the device in Embodiment I, the reactor is internally provided with a neutron irradiation unit directly opposite the growing area, where the neutron irradiation unit is a neutron source, and specific equipment may employ a laser neutron source.

A preparation method for the thin film is as follows:
1. Substrate cleaning:
a sapphire substrate is placed in an ultrasonic cleaning machine containing cleaning liquid and undergoes ultrasonic cleaning for 1 min, and
the substrate is taken out, and then the cleaning liquid remaining on the surface of the substrate is blown dry with nitrogen.
2. A proper quartz rotary base is selected according to the size of the substrate, the sapphire substrate is horizontally fixed to the rotary base, then the rotary base is sent into a reactor by a mobile unit, and the reactor is sealed with a sealing flange plate.
3. The rotary base is adjusted to make the substrate located 2 mm directly above the second buffer plate, where the substrate is parallel to the second buffer plate.
4. A reaction source solution is prepared as follows: 18.5 grams of gallium acetylacetonate powder is dissolved in 2 liters of deionized water to prepare a gallium source solution with a concentration of about 0.025 mol/L, and the prepared reaction source solution is added to an atomization unit.
5. Residual gas in the reactor is evacuated with nitrogen, and preheating is carried out to the reactor. A temperature of the reactor is set to be 650 °C.
6. After preheating, the atomization unit is started, and in the atomization unit, the reaction resource is atomized through an ultrasonic atomization method to form uniform droplets, where an ultrasonic atomization frequency is 3 MHz.
7. A carrier gas is introduced, where nitrogen is employed as the carrier gas, with a flow rate of 400 sccm. The carrier gas entrains the droplets to enter the reactor, and a gallium oxide thin film grows on the substrate. The reactor is kept at a growth temperature and the gallium oxide thin film is begun to grow, where the growth time is set to be 10 min.
8. The atomization unit is turned off, the neutron irradiation unit is initiated to carry out neutron irradiation on the grew thin film, where an irradiation dose is set to be 100 kGy with a duration of 2 min, and upon completion of irradiation, heating is kept 10 min.
9. Steps 7 and 8 are repeated for five times.
10. Upon completion of the growth of the gallium oxide thin film, an atomization device and the carrier gas are turned off, and the temperature of the reactor is kept for 3 min; then the carrier gas is initiated and nitrogen is continuously introduced to evacuate residual reactants and byproducts from a reaction chamber, and the temperature in the reaction chamber is gradually cooled to a room temperature, and then a sample is taken out.

Compared with Embodiment I, the thin film prepared in this embodiment has reduced defect density, and its film thickness uniformity changes little.

Embodiment VI: Epitaxial growth of two-inch α-Ga₂O₃ thin film on sapphire substrate in additional electric field environment

This thin film is prepared by using the same vertical device for mist chemical vapor deposition of a large-size semiconductor thin film as in Embodiment I. In addition, on the basis of the device in Embodiment I, electrode plates for generating an accelerated electric field are also arranged at two ends of the reactor, a direction of the accelerated electric field is consistent with that of the carrier gas, and an electrode for generating a high-voltage electrostatic field is also arranged at a gas outlet of the atomization unit.

A preparation method for the thin film is as follows:
1. Substrate cleaning:
a sapphire substrate is placed in an ultrasonic cleaning machine containing cleaning liquid and undergoes ultrasonic cleaning for 1 min, and
the substrate is taken out, and then the cleaning liquid remaining on the surface of the substrate is blown dry with nitrogen.
2. A proper quartz rotary base is selected according to the size of the substrate, the sapphire substrate is horizontally fixed onto the rotary base, then the rotary base is sent into a reactor by a mobile unit, and the reactor is sealed with a sealing flange plate.
3. The rotary base is adjusted to make the substrate located 2 mm directly above the second buffer plate, where the substrate is parallel to the second buffer plate.
4. A reaction source solution is prepared as follows: 18.5 grams of gallium acetylacetonate powder is dissolved in 2 liters of deionized water to prepare a gallium source solution with a concentration of about 0.025 mol/L, and the prepared reaction source solution is added to an atomization unit.
5. Residual gas in the reactor is evacuated with nitrogen, and preheating is carried out to the reactor. A temperature of the reactor is set to be 650 °C.
6. After preheating, the atomization unit is started, and in the atomization unit, the reaction resource is atomized through an ultrasonic atomization method to form uniform droplets, where an ultrasonic atomization frequency is 3 MHz.
7. A high-voltage electrostatic field is activated to charge the droplets, where a field strength of the high-voltage electrostatic field is 10 kV/m;
meanwhile, the accelerated electric field is activated, where a field strength of the accelerated electric field is 1 kV/m.
8. A carrier gas is introduced, where nitrogen is employed as the carrier gas, with a flow rate of 200 sccm. The carrier gas entrains the droplets to enter the reactor, and a gallium oxide thin film grows on the substrate. The reactor is kept at a growth temperature and the gallium oxide thin film is begun to grow, where the growth time is set to be 30 min.
9. Upon completion of the growth of the gallium oxide thin film, an atomization device and the carrier gas are turned off, and the temperature of the reactor is kept for 3 min; then the carrier gas is initiated and nitrogen is continuously introduced to evacuate residual reactants and byproducts from a reaction chamber, and the temperature in the reaction chamber is gradually cooled to a room temperature, and then a sample is taken out.

Compared with Embodiment I, a growth rate of the thin film prepared in this embodiment is increased, the thickness of the thin film is increased, and the thickness uniformly changes little.

Therefore, by using the device provided by the present disclosure, the gallium oxide thin films with different thicknesses can be grew by changing the growth time, gallium oxide thin films with different crystal forms can be grew by changing the growth temperature of the reaction chamber, and gallium oxide thin films with homoepitaxy and heteroepitaxy can be respectively implemented by using different substrates.

### Comparative Example 1: Tilt Angle of Inclined Hole

The difference from Embodiment I is that an included angle between the central axis of the inclined hole and the surface normal of the second buffer plate is 5°, so that the raw material mist is directed toward the surface of the substrate at 5°.

The uniformity of the obtained thin film is poor than that of the thin film in the embodiment I and the periodic thickness fluctuation of the film indicates that the included angle should not be too small.

### Comparative Example 2: Tilt Angle of Inclined Hole

The difference from Embodiment I is that an included angle between the central axis of the inclined hole and the surface normal of the second buffer plate is 80°, so that the raw material mist is directed toward the substrate surface at 80°.

The thickness uniformity of the obtained thin film is slightly poorer than that of the thin film in the embodiment I, and an average thickness of the obtained thin film is thinner than that in the embodiment I, indicating that excessively large angle is not conducive to the growth of the thin film.

### Comparative Example 3: Spacing Between Holes

The difference from Embodiment I is that the distance between every two adjacent straight holes is 15 mm.

The thickness uniformity of the obtained thin film deteriorates significantly, the increase of the spacing between holes actually leads to the decrease of hole density, resulting in nonuniform thickness of the thin film.

### Comparative Example 4: Hole Diameter

The difference from Embodiment I is that a diameter of the straight hole is 20 mm, and a diameter of the inclined hole is 20 mm.

The thickness uniformity of the obtained thin film deteriorates, the excessively large hole diameter leads to the decrease of the buffer effect, resulting in the nonuniform thickness of the thin film.

### Comparative Example 5: Setting of a Buffer Plate

The difference from Embodiment I is that there is only the second buffer plate.

The thickness uniformity of the thin film deteriorates, and an edge of the thin film is thinned, which is caused by nonuniform mist flow velocity distribution caused by the absence of the first buffer plate.

### Comparative Example 6: No Buffer Plates

The difference from Embodiment I is that there is no first buffer plate and second buffer plate (this comparative example may also be considered as an extreme case of a large hole in Comparative example 4, that is, the diameter of the hole equals to that of the cylindrical segment, that is, there are no two buffer plates).

The thickness uniformity of the obtained thin film deteriorates.

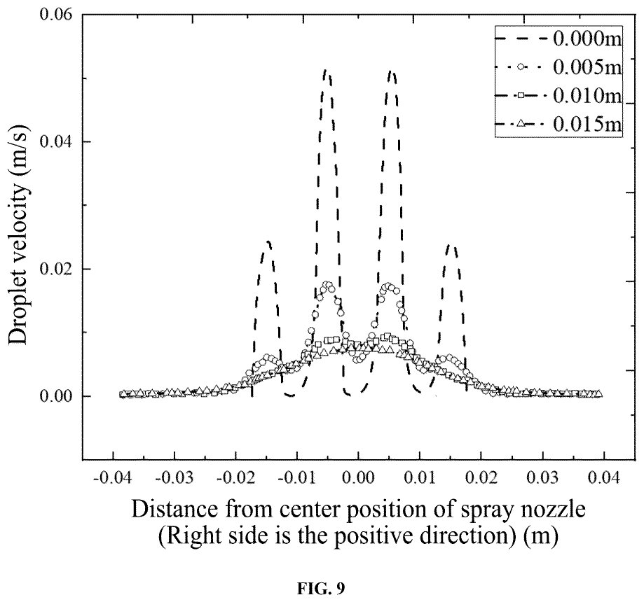

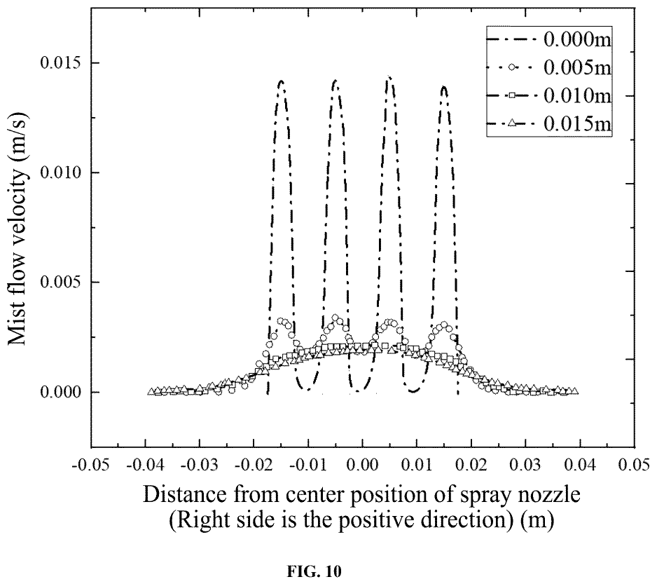

FIG. 9 shows a cross-sectional flow velocity distribution of a gas ejected from a spray showerhead without a buffer structure in this comparative example, and FIG. 10 shows cross-sectional flow velocity distribution of a gas ejected from a spray showerhead with a buffer structure according to Embodiment I. As can be learned from the figures that when there is the buffer structure, the mist flow velocity is more uniform, and thus the thin film with more uniform thickness can be obtained.

In conclusion, a buffer showerhead is arranged in a reactor of a device for mist chemical vapor deposition of a large-size semiconductor thin film provided by the present disclosure. By designing a structure of the buffer showerhead, epitaxial growth of large-size gallium oxide thin films with various crystal phases and uniform thickness can be achieved.

The foregoing is only the preferred embodiment of the present disclosure, and it is not used to limit the present disclosure. Any modification, equivalent substitution, improvement and like made under the spirit and principles of the present disclosure should be included within the scope of protection of the present disclosure.

What is claimed is:

1. A device for mist chemical vapor deposition of a large-size semiconductor thin film, comprising an atomization unit, a reactor, a buffer showerhead, and a rotary base, wherein
the buffer showerhead is arranged inside the reactor, and the buffer showerhead comprises a conveying pipe, a conical transition segment and a cylindrical segment connected in sequence from left to right; the conveying pipe passes through one end of the reactor and is connected to the atomization unit, and the atomization unit is further provided with a carrier gas input port; a first buffer plate and a second buffer plate are arranged in the cylindrical segment in sequence from left to right, and the first buffer plate and the second buffer plate divide the cylindrical segment into three portions, and the three portions are a first buffer area, a second buffer area and a growing area; the first buffer plate is of a conical plate structure, an apex of the conical plate structure is away from the second buffer plate, and the first buffer plate is provided with a plurality of straight holes perpendicular to the second buffer plate, and the second buffer plate is provided with a plurality of inclined holes; the rotary base directly opposite to the second buffer plate is arranged at the growing area, and a substrate is fixed onto the rotary base and is surrounded by a cylindrical segment of the growing area; the rotary base is driven to rotate by a first motor arranged outside the reactor, the first motor is mounted on a mobile unit, and the mobile unit drives the first motor and the rotary base to move toward a direction close to or away from the second buffer plate;
wherein each of the straight holes has a diameter of 2 mm-10 mm, a distance between every two adjacent straight holes is 2 mm-5 mm, and the inclined hole has a diameter of 2 mm-10 mm;
the diameter of the straight hole is equal to the diameter of the inclined hole;
the inclined holes and the straight holes are equal in number and in a one-to-one correspondence; and
an included angle between a central axis of the inclined hole and a surface normal of the second buffer plate is 30°-70°.

2. The device for mist chemical vapor deposition of a large-size semiconductor thin film according to claim 1, wherein the cylindrical segment has a length of 50 mm-300 mm, a distance between a center of the first buffer plate and a center of the second buffer plate is 10 mm-200 mm, an included angle α of an apex angle of the first buffer plate is 90°-175°, and a distance between the second buffer plate and the substrate is 0.5 mm-50 mm.

3. The device for mist chemical vapor deposition of a large-size semiconductor thin film according to claim 1, wherein the mobile unit comprises a motion bracket and a drive mechanism;
the drive mechanism comprises a screw, a sliding rod, a second motor, and a bracket; the screw and the sliding rod are arranged on the bracket in parallel, the second motor is in transmission connection with the screw, the motion bracket is slidingly arranged on the sliding rod, the motion bracket is threaded to the screw, and the first motor is mounted on the motion bracket.

4. The device for mist chemical vapor deposition of a large-size semiconductor thin film according to claim 1, wherein the reactor comprises a cylinder with two open ends and sealing flange plates fixed to the two ends of the cylinder, the conveying pipe passes through one sealing flange plate, and a rotating shaft for connecting the rotary base and the first motor passes through an other sealing flange plate; an exhaust pipe is also connected to the other sealing flange plate, and the exhaust pipe is connected to an exhaust treatment unit; and a heating layer is also arranged on a sidewall of the cylinder.

5. The device for mist chemical vapor deposition of a large-size semiconductor thin film according to claim 1, wherein a side surface, directly opposite to the second buffer plate, of the rotary base is provided with a groove, a center of the groove is provided with a boss for placing the substrate, two to six bolts are screwed to a sidewall of the groove, and one end, extending into the groove, of each of the bolts is rotatably connected to a top plate.

6. The device for mist chemical vapor deposition of a large-size semiconductor thin film according to claim 1, wherein a neutron irradiation unit is arranged inside the reactor directly opposite the growing area.

7. The device for mist chemical vapor deposition of a large-size semiconductor thin film according to claim 1, wherein electrode plates for generating an accelerated electric field are also arranged at two ends of the reactor, a field strength range of the generated accelerated electric field is 500 V-10 kV/m, and a direction of the accelerated electric field is consistent with a carrier gas direction; and an electrode for generating a high-voltage electrostatic field is also arranged at a gas outlet of the atomization unit.

8. A method for mist chemical vapor deposition of a large-size semiconductor thin film, wherein the method uses the device for mist chemical vapor deposition of a large-size semiconductor thin film according to claim 1, and comprises the following steps:
S1, fixing a cleaned substrate onto the rotary base, and moving, by the mobile unit, the substrate to the growing area to directly face the second buffer plate;
S2, adding a configured reaction source solution into the atomization unit;
S3, evacuating residual gas in the reactor with nitrogen, and preheating the reactor;
S4, starting the atomization unit after preheating, and atomizing the reaction source solution to form uniform droplets;
S5, introducing the carrier gas, wherein the carrier gas entrains the droplets to enter the reactor, and growing a gallium oxide thin film on the substrate; and
S6, upon completion of gallium oxide thin film growth, turning off an atomization device and the carrier gas, and maintaining a temperature of the reactor; starting continuous introduction of the carrier gas to evacuate residual reactants and byproducts from a reaction chamber, gradually cooling the reaction chamber to a room temperature, and taking out a sample.

9. The method for mist chemical vapor deposition of a large-size semiconductor thin film according to claim 8, wherein the method further comprises the following steps: in S5, growing the thin film for 5 min-60 min, turning off the atomization device, turning on a neutron irradiation unit to perform neutron irradiation on the grown thin film, wherein an irradiation dose is set to 500 kGy-5000 kGy with a duration of 30 s-300 s; upon completion of irradiation, maintaining heating for 3 min-15 min; and repeating the step for 2-10 times; or
the method further comprises the following steps: after a forming of uniform droplets in S4, activating a high-voltage electrostatic field to charge the droplets, wherein a field strength range of the high-voltage electrostatic field is 5 kV-100 kV/m; meanwhile activating an accelerated electric field, wherein a field strength range of the accelerated electric field is 500 V-10 kV/m.

10. The method for mist chemical vapor deposition of a large-size semiconductor thin film according to claim 8, wherein the cylindrical segment has a length of 50 mm-300 mm, a distance between a center of the first buffer plate and a center of the second buffer plate is 10 mm-200 mm, an included angle α of an apex angle of the first buffer plate is 90°-175°, and a distance between the second buffer plate and the substrate is 0.5 mm-50 mm.

11. The method for mist chemical vapor deposition of a large-size semiconductor thin film according to claim 8, wherein the mobile unit comprises a motion bracket and a drive mechanism; the drive mechanism comprises a screw, a sliding rod, a second motor, and a bracket; the screw and the sliding rod are arranged on the bracket in parallel, the second motor is in transmission connection with the screw, the motion bracket is slidingly arranged on the sliding rod, the motion bracket is threaded to the screw, and the first motor is mounted on the motion bracket.

12. The method for mist chemical vapor deposition of a large-size semiconductor thin film according to claim 8, wherein the reactor comprises a cylinder with two open ends and sealing flange plates fixed to the two ends of the cylinder, the conveying pipe passes through one sealing flange plate, and a rotating shaft for connecting the rotary base and the first motor passes through an other sealing flange plate; an exhaust pipe is also connected to the other sealing flange plate, and the exhaust pipe is connected to an exhaust treatment unit; and a heating layer is also arranged on a sidewall of the cylinder.

13. The method for mist chemical vapor deposition of a large-size semiconductor thin film according to claim 8, wherein a side surface, directly opposite to the second buffer plate, of the rotary base is provided with a groove, a center of the groove is provided with a boss for placing the substrate, two to six bolts are screwed to a sidewall of the groove, and one end, extending into the groove, of each of the bolts is rotatably connected to a top plate.

14. The method for mist chemical vapor deposition of a large-size semiconductor thin film according to claim 8, wherein a neutron irradiation unit is arranged inside the reactor directly opposite the growing area.

15. The method for mist chemical vapor deposition of a large-size semiconductor thin film according to claim 8, wherein electrode plates for generating an accelerated electric field are also arranged at two ends of the reactor, a field strength range of the generated accelerated electric field is 500 V-10 kV/m, and a direction of the accelerated electric field is consistent with a carrier gas direction; and an electrode for generating a high-voltage electrostatic field is also arranged at a gas outlet of the atomization unit.

16. The method for mist chemical vapor deposition of a large-size semiconductor thin film according to claim 9, wherein the cylindrical segment has a length of 50 mm-300 mm, a distance between a center of the first buffer plate and a center of the second buffer plate is 10 mm-200 mm, an included angle α of an apex angle of the first buffer plate is 90°-175°, and a distance between the second buffer plate and the substrate is 0.5 mm-50 mm.

17. The method for mist chemical vapor deposition of a large-size semiconductor thin film according to claim 9, wherein the mobile unit comprises a motion bracket and a drive mechanism; the drive mechanism comprises a screw, a sliding rod, a second motor, and a bracket; the screw and the sliding rod are arranged on the bracket in parallel, the second motor is in transmission connection with the screw, the motion bracket is slidingly arranged on the sliding rod, the motion bracket is threaded to the screw, and the first motor is mounted on the motion bracket.

18. The method for mist chemical vapor deposition of a large-size semiconductor thin film according to claim 9, wherein the reactor comprises a cylinder with two open ends and sealing flange plates fixed to the two ends of the cylinder, the conveying pipe passes through one sealing flange plate, and a rotating shaft for connecting the rotary base and the first motor passes through an other sealing flange plate; an exhaust pipe is also connected to the other sealing flange plate, and the exhaust pipe is connected to an exhaust treatment unit; and a heating layer is also arranged on a sidewall of the cylinder.

19. The method for mist chemical vapor deposition of a large-size semiconductor thin film according to claim 9, wherein a side surface, directly opposite to the second buffer plate, of the rotary base is provided with a groove, a center of the groove is provided with a boss for placing the substrate, two to six bolts are screwed to a sidewall of the groove, and one end, extending into the groove, of each of the bolts is rotatably connected to a top plate.

20. The method for mist chemical vapor deposition of a large-size semiconductor thin film according to claim 9, wherein a neutron irradiation unit is arranged inside the reactor directly opposite the growing area.
